(19) United States
(12) Patent Application Publication
(10) Pub. No.: US 2025/0120267 A1
(43) Pub. Date: Apr. 10, 2025

(54) DISPLAY DEVICE AND MANUFACTURING METHOD THEREOF

(71) Applicant: Samsung Display Co., LTD., Yongin-si (KR)

(72) Inventors: Joo Young KIM, Yongin-si (KR); Young Joo NAM, Yongin-si (KR); Do Hyun PARK, Yongin-si (KR); Young Jin PARK, Yongin-si (KR)

(21) Appl. No.: 18/659,702

(22) Filed: May 9, 2024

(30) Foreign Application Priority Data
Oct. 4, 2023 (KR) 10-2023-0131915

(51) Int. Cl. H10K 59/131; H10K 59/12; H10K 59/90

(52) U.S. Cl. CPC H10K 59/131; H10K 59/1201; H10K 59/90

(57) ABSTRACT

A display device includes a display panel, a shielding layer which is disposed at a lower end of the display panel and includes a plurality of alignment marks, and a printed circuit board which is aligned on the shielding layer, based on the plurality of alignment marks, and contacts at least a portion of the shielding layer. The shielding layer includes conductive members electrically connecting the printed circuit board and the shielding layer.

The application claims priority to Korean patent application No. 10-2023-0131915, filed on Oct. 4, 2023, and all the benefits accruing therefrom under 35 U.S.C. § 119, the content of which in its entirety is herein incorporated by reference.

### BACKGROUND

### 1. Field

The disclosure generally relates to an electronic device, and more particularly, to a display device and a manufacturing method thereof.

### 2. Description of the Related Art

With the development of technologies, an electronic device may include an electronic component performing various functions therein. The electronic component may include a main printed circuit board of the electronic device. The electronic component may be connected to the main printed circuit board through a connector to be supplied with power or to transmit/receive signals.

### SUMMARY

Embodiments provide a display device and a manufacturing method thereof, in which a printed circuit board is aligned on a shielding layer, based on alignment marks. In an embodiment, the display device may include alignment marks capable of checking whether the printed circuit board has been successfully aligned. Accordingly, during a manufacturing process of the display device, it may be checked whether the shielding layer and the printed circuit board are electrically connected to each other by conductive members of the shielding layer.

In an embodiment of the disclosure, a display device includes: a display panel; a shielding layer disposed at a lower end of the display panel, the shielding layer including a plurality of alignment marks; and a printed circuit board aligned on the shielding layer, based on the plurality of alignment marks, the printed circuit board being in contact with at least a portion of the shielding layer, wherein the shielding layer includes conductive members electrically connecting the printed circuit board and the shielding layer to each other.

In an embodiment, the printed circuit board may overlap with at least a portion of a contact area of the shielding layer. The plurality of alignment marks may be disposed on the contact area.

In an embodiment, at least one of the plurality of alignment marks may overlap with the printed circuit board.

In an embodiment, the display device may further include a printed circuit board cover covering the printed circuit board. Corners of the printed circuit board and the printed circuit board cover may be cut so that the plurality of alignment marks is exposed.

In an embodiment, the plurality of alignment marks may include a first alignment mark disposed at one side of the shielding layer and a second alignment mark which is disposed at an opposite side of the shielding layer and is symmetrically disposed with the first alignment mark.

In an embodiment, a distance between an outer side of the first alignment mark and an outer side of the second alignment mark in a predetermined direction perpendicular to a direction in which the shielding layer and the printed circuit board are arranged may be smaller than a length of the printed circuit board in the predetermined direction.

In an embodiment, a distance between an outer side of the first alignment mark and an outer side of the second alignment mark in a predetermined direction in which the shielding layer and the printed circuit board are arranged may be smaller than a length of the printed circuit board in the predetermined direction.

In an embodiment, the shielding layer may include at least one of aluminum (Al) and copper (Cu).

In an embodiment, the plurality of alignment marks may be imprinted in the shielding layer.

In an embodiment of the disclosure, a method of manufacturing a display device includes: preparing a display panel including a bending area; disposing a shielding layer including a plurality of alignment marks at a lower end of the display panel; and

aligning a printed circuit board on the shielding layer, based on the plurality of alignment marks, as the bending area is bent, wherein the shielding layer includes conductive members electrically connecting the printed circuit board and the shielding layer to each other.

In an embodiment, the printed circuit board may be disposed to overlap with at least a portion of a contact area of the shielding layer. The alignment marks may be disposed on the contact area.

In an embodiment, at least one of the alignment marks may overlap with the printed circuit board.

In an embodiment, the method may further include disposing a printed circuit board cover on the printed circuit board. Corners of the printed circuit board and the printed circuit board cover may be cut so that the plurality of alignment marks is exposed.

In an embodiment, the alignment marks may include a first alignment mark disposed at one side of the shielding layer and a second alignment mark which is disposed at an opposite side of the shielding layer and is symmetrically disposed with the first alignment mark.

In an embodiment, a distance between an outer side of the first alignment mark and an outer side of the second alignment mark in a predetermined direction perpendicular to a direction in which the shielding layer and the printed circuit board are arranged may be smaller than a length of the printed circuit board in the predetermined direction.

In an embodiment, a distance between an outer side of the first alignment mark and an outer side of the second alignment mark in a predetermined direction in which the shielding layer and the printed circuit board are arranged may be smaller than a length of the printed circuit board in the predetermined direction.

In an embodiment, the shielding layer may include at least one of aluminum (Al) and copper (Cu).

In an embodiment, the plurality of alignment marks may be imprinted in the shielding layer.

### BRIEF DESCRIPTION OF THE DRAWINGS

Embodiments, features and advantages will now be described more fully hereinafter with reference to the accompanying drawings.

FIG. 1 is a perspective view of an embodiment of a display device in accordance with the disclosure.

FIG. 2 is an exploded perspective view of the display device shown in FIG. 1.

FIG. 3 is an exploded perspective view illustrating an embodiment of a protective layer shown in FIG. 2.

FIG. 4 is a plan view illustrating an embodiment of a shielding layer and a printed circuit board before a bending area shown in FIG. 2 is bent.

FIG. 5 is a plan view illustrating an embodiment of the shielding layer and the printed circuit board after the bending area shown in FIG. 2 is bent.

FIG. 6 is a plan view illustrating a comparative example in which the printed circuit board shown in FIG. 5 is not successfully aligned on the shielding layer.

FIG. 7 is a flowchart illustrating an embodiment of a manufacturing method of the display device in accordance with the disclosure.

FIG. 8 is a flowchart illustrating an embodiment of a manufacturing method of the display device in accordance with the disclosure.

FIG. 9 is a plan view illustrating an embodiment of a shielding layer and a printed circuit board cover in operation S840 shown in FIG. 8.

### DETAILED DESCRIPTION

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it may be directly connected or coupled to the another element or be indirectly connected or coupled to the another element with one or more intervening elements interposed therebetween. The technical terms used herein are used only for the purpose of illustrating an illustrative embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” may be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” may be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the drawing figures. It will be understood that the spatially relative terms, as well as the illustrated configurations, are intended to encompass different orientations of the apparatus in use or operation in addition to the orientations described herein and depicted in the drawing figures. For example, if the apparatus in the drawing figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly. Illustrative embodiments may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, dimensions may be exaggerated for clarity of illustration. It will be understood that when an element is also referred to as being “between” two elements, it may be the only element between the two elements, or one or more intervening elements may also be present. Like reference numerals refer to like elements throughout.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the predetermined shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

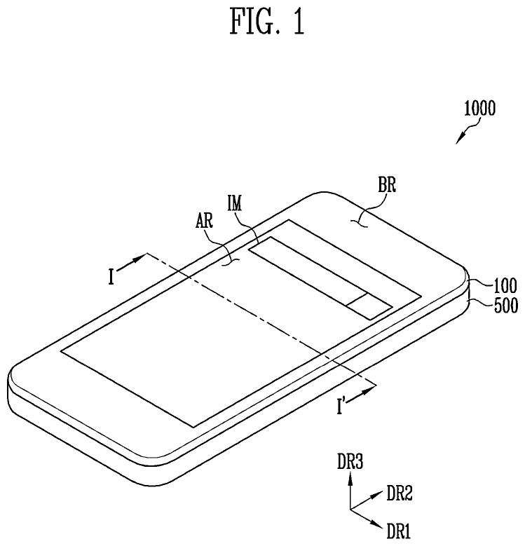

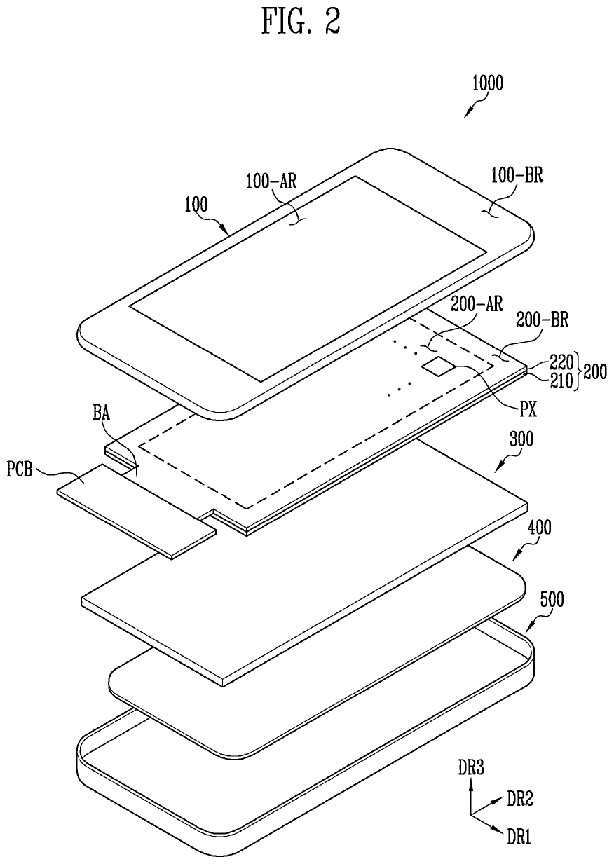

FIG. 1 is a perspective view of an embodiment of a display device in accordance with the disclosure. FIG. 2 is an exploded perspective view of the display device shown in FIG. 1.

In FIG. 1, a portable terminal is illustrated as an example to which the display device in the embodiment of the disclosure is applied. The portable terminal may include a tablet personal computer (“PC”), a smartphone, a personal digital assistant (“PDA”), a portable multimedia player (“PMP”), a game device, a watch-type electronic device, or the like. However, the disclosure is not limited thereto. The disclosure may be used not only large-sized electronic devices such as a television and an external advertisement board but also for small- and medium-sized electronic devices such as a PC, a notebook computer, a vehicle navigation unit, and a camera. These devices are merely provided as embodiments, and the display device may be employed in other electronic devices unless the electronic devices deviate from the concept of the disclosure.

As shown in FIG. 1, the display device 1000 may include a plurality of areas divided on a display surface. In an embodiment, the display device 1000 may include a display area AR in which an image IM is displayed and a non-display area BR adjacent to the display area AR, for example.

FIG. 1 illustrates an Internet search window in an embodiment of the image IM. In the disclosure, the display area AR may have, e.g., a quadrangular shape. The non-display area BR may be disposed while surrounding the display area AR.

Referring to FIGS. 1 and 2, the display device 1000 may include a window member 100, a display panel 200, a protective layer 300, a bracket 400, and a rear case 500.

The window member 100 may be disposed on the top of the display panel 200. Accordingly, the window member 100 may protect a display surface (e.g., a top surface in a third direction DR3) of the display panel 200. Also, the window member 100 may be coupled to the display panel 200. In an embodiment, the window member 100 may be coupled to the display panel 200 while covering the display surface of the display panel 200, for example.

The window member 100 may include a display area 100-AR which allows the image IM provided by the display panel 200 to be transmitted therethrough and a non-display area 100-BR adjacent to the display area 100-AR.

The window member 100 may include an optically transparent material. In an embodiment, the window member 100 may include glass or plastic, for example. Also, the window member 100 may have a multi-layer structure or a single-layer structure. In an embodiment, the window member 100 may include a plurality of films coupled to each other by an adhesive or include a glass substrate and a plastic film, which are coupled to each other by an adhesive, for example.

The display panel 200 may include a substrate 210, an encapsulation layer 220, a plurality of pixels PX, a bending area BA, and a printed circuit board PCB.

The display panel 200 may have the display surface on which the image IM is displayed and a back surface opposite to the display surface. The display surface may be defined as a top surface of the encapsulation layer 220, and the back surface may be defined as a bottom surface of the substrate 210.

The display panel 200 may include a display area 200-AR and a non-display area 200-BR. The display area 200-AR may be an area in which the image IM is displayed, and correspond to the display area 100-AR of the window member 100. The non-display area 200-BR may be adjacent to the display area 200-AR, and correspond to the non-display area 100-BR of the window member 100. The display area 200-AR in which the image IM is displayed is parallel to a plane defined by a first direction DR1 and a second direction DR2, and a normal direction of the display area 200-AR is indicated by the third direction DR3. However, directions indicated by the above-described directions are relative concepts, and may be changed into other directions.

The substrate 210 may be a rigid or flexible substrate or film. In an embodiment, the substrate 210 may be configured as a rigid substrate including glass or tempered glass, a flexible substrate (or thin film) including plastic or metal, or at least one insulating layer, for example. The material and/or property of the substrate 210 are/is not particularly limited.

The encapsulation layer 220 may be disposed on the substrate 210. When the encapsulation layer 220 is provided in the form of an encapsulation film, the encapsulation layer 220 may include an inorganic layer and/or an organic layer. The encapsulation layer 220 may protect the pixels PX from moisture and oxygen. Also, the encapsulation layer 220 may protect the pixels PX from foreign matters such as dust particles.

Pixels PX disposed along the first direction DR1 among the plurality of pixels PX may form a pixel row, and pixels PX disposed along the second direction DR2 among the plurality of pixels PX may form a pixel column. Each of the pixels PX may include a plurality of sub-pixels. In an embodiment, each of the plurality of pixels PX may include a first pixel which emits light of a red color, a second pixel which emits light of a green color, and a third pixel which emits light of a blue color, for example. Each of the plurality of pixels PX may include a light-emitting element

and a pixel circuit which drives the light-emitting element. In some embodiments, the light-emitting element may be provided in various forms. In an embodiment, the light-emitting element may be an inorganic light-emitting element including an inorganic material, for example. In some embodiments, the light-emitting element may be an organic light-emitting diode (“OLED”).

The bending area BA may be a portion at which the display panel 200 is folded. The bending area BA may be bent downwardly of the protective layer 300. In an embodiment, as the bending area BA is bent in the opposite direction of the third direction DR3, the printed circuit board PCB may be disposed to overlap with the protective layer 300, for example.

The bending area BA may include a flexible printed circuit board (“FPCB”). Therefore, the bending area BA may electrically connect the display panel 200 and the printed circuit board PCB to each other. In an embodiment, the display panel 200 and the printed circuit board PCB may exchange driving signals through the FPCB, for example. The driving signals may be various signals for driving the display device 1000, including a driving voltage, a gate signal, a data signal, or the like.

The printed circuit board PCB may output signals to the display panel 200 through the bending area BA or receive signals from the display panel 200 through the bending area BA. The printed circuit board PCB may be disposed on a bottom surface of the protective layer 300 in a state in which the printed circuit board PCB is coupled to the protective layer 300 as the bending area BA is bent. The printed circuit board PCB may include a connector for receiving signals transmitted from the outside.

In some embodiments, the display device 1000 may further include a touch panel. The touch panel may be disposed between the window member 100 and the display panel 200. However, the disclosure is not limited thereto. In some embodiments, the touch panel may be disposed inside the display panel 200. The touch panel may operate in a resistive type, a capacitive type, or an electromagnetic type, and acquire coordinate information of a point at which a touch event occurs.

The protective layer 300 may be disposed on the back surface of the display panel 200. The protective layer 300 may be disposed between the display panel 200 and the printed circuit board PCB in a state in which the protective layer 300 is coupled to the display panel 200 and the printed circuit board PCB.

The bracket 400 may support the display panel 200 and the protective layer 300. One surface of the bracket 400 may be attached to the protective layer 300, and a space in which electronic components are to be disposed (e.g., mounted) may be provided at an opposite surface of the bracket 400.

The rear case 500 may accommodate the display panel 200 and the protective layer 300, and be coupled to the window member 100. The rear case 500 may include plastic or metal. In an embodiment of the disclosure, the rear case 500 may be omitted.

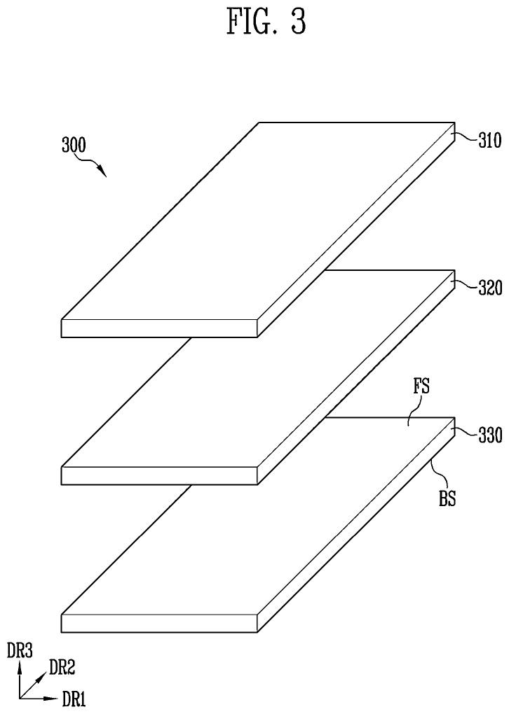

FIG. 3 is an exploded perspective view illustrating an embodiment of the protective layer shown in FIG. 2.

Referring to FIG. 3, the protective layer may include a light-blocking layer 310, a heat dissipation layer 320, and a shielding layer 330.

The light-blocking layer 310 may block light incident into the display panel 200. In an embodiment, the light-blocking layer 310 may be disposed on the back surface of the display panel 200 to block light incident in the third direction DR3 and/or the opposite direction of the third direction DR3 into the display panel 200, for example.

In some embodiments, the light-blocking layer 310 may adhere to the display panel 200. In an embodiment, an adhesive layer of the light-blocking layer 310 may allow the light-blocking layer 310 to adhere closely to the back surface of the display panel 200, for example. In some embodiments, the adhesive layer may include an Optically Clear Adhesive (“OCA”) or an Optically Clear Resin (“OCR”).

A surface of the light-blocking layer 310 may have a predetermined pattern. In an embodiment, the surface of the light-blocking layer 310 may be embossed to have the predetermined pattern, and accordingly, a probability may be reduced that bubbles will occur between the display panel 200 and the light-blocking layer 310 when the display panel 200 and the light-blocking layer 310 adhere closely to each other, for example.

The light-blocking layer 310 may include a resin layer including polyethylene terephthalate (“PET”), or the like and a light interrupting layer disposed on a back surface of the resin layer. The light interrupting layer may be a coating layer including a black tape or a light interrupting material.

In some embodiments, the light-blocking layer 310 may further include a buffering member. Accordingly, the light-blocking layer 310 may disperse impact applied to the display panel 200 and the window member 100. In an embodiment, the buffering member may absorb a portion of impact applied to the display panel 200 and the window member 100, so that damage of the display panel 200 and the window member 100 may be prevented, for example.

The buffering member may include or consist of a polymer resin material. In an embodiment, the buffering member may include or consist of polyurethane, polycarbonate, polypropylene, or polyethylene. Also, the buffering member may include or consist of a sponge formed by foam molding a rubber solution, a urethane-based material, or an acrylic-based material.

The heat dissipation layer 320 may be disposed on a back surface of the light-blocking layer 310. In an embodiment, the heat dissipation layer 320 may be disposed between the light-blocking layer 310 and a shielding layer 330, for example.

The heat dissipation layer 320 may include a material having a relatively high thermal conductivity. Accordingly, heat generated in the display panel 200 may be effectively radiated. In an embodiment, the heat dissipation layer 320 may absorb heat generated in the display panel 200, thereby radiating the absorbed heat through the relatively high thermal conductivity, for example.

The heat dissipation layer 320 may include graphite. The graphite may be a plate-shaped structure in which carbon atoms are connected to each other in a horizontal direction. Accordingly, the heat dissipation layer 320 may have a thermal conductivity in the horizontal direction, which is higher than a thermal conductivity in a vertical direction, and have an excellent heat dissipation effect.

The shielding layer 330 may be disposed on a back surface of the heat dissipation layer 320. In an embodiment, a front surface FS of the shielding layer 330 and the back surface of the heat dissipation layer 320 may contact each other, for example.

A back surface BS of the shielding layer 330 may be opposite to the front surface FS of the shielding layer 330. In an embodiment, the back surface BS of the shielding layer 330 may be opposite to the front surface FS of the shielding layer 330 in the third direction DR3, for example. The back surface BS of the shielding layer 330 may overlap with the printed circuit board PCB (refer to FIG. 2). In an embodiment, one surface of the printed circuit board PCB may contact the back surface BS of the shielding layer 330, for example.

The shielding layer 330 may include at least one metal among various metals including aluminum (Al), copper (Cu), silver (Ag), magnesium (Mg), platinum (Pt), palladium (Pd), gold (Au), nickel (Ni), neodymium (Nd), iridium (Ir), chromium (Cr), titanium (Ti), molybdenum (Mo), or the like, or alloys including the same, and be formed as a multi-layer or a single layer, which includes the corresponding material. Also, the shielding layer 330 may include a conductive oxide such as indium tin oxide (“ITO”), indium zinc oxide (“IZO”), indium tin zinc oxide (“ITZO”), zinc oxide (ZnO), aluminum-doped zinc oxide (“AZO”), gallium-doped zinc oxide (“GZO”), zinc tin oxide (“ZTO”), gallium tin oxide (“GTO”), or fluorine-doped tin oxide (“FTO”), or at least one conductive material among conductive polymers such as poly(3,4-ethylenedioxythiophene) (“PEDOT”).

The shielding layer 330 may decrease the intensity of an electromagnetic wave formed in the display panel 200 and/or the printed circuit board PCB (refer to FIG. 2). In an embodiment, the shielding layer 330 may absorb an electromagnetic wave leaked from the display panel 200 and/or the printed circuit board PCB. The electromagnetic wave absorbed in the shielding layer 330 may be converted into electric and magnetic energies, and the shielding layer 330 may weaken the intensity of the electromagnetic wave formed in the display panel 200 and/or the printed circuit board

PCB. Thus, the shielding layer 330 prevents the electromagnetic wave formed in the display panel 200 and/or the printed circuit board PCB from being leaked to an electrical circuit included in the display device 1000, thereby improving the reliability of the display device 1000 in driving of the display device 1000.

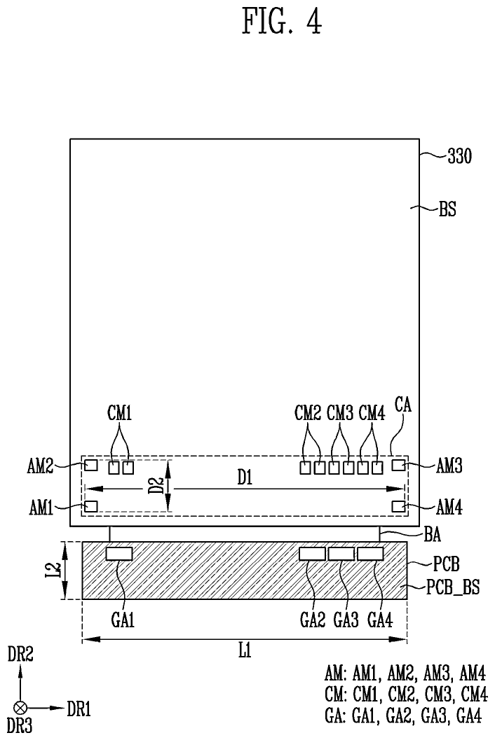

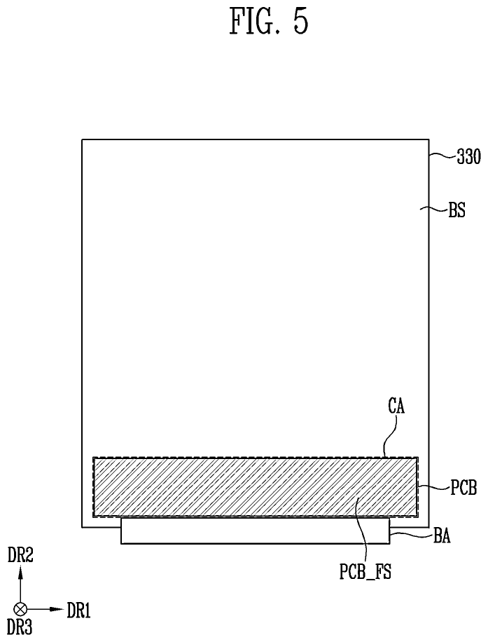

Also, the shielding layer 330 may contact a ground surface of the printed circuit board PCB, thereby decreasing the intensity of an electromagnetic wave formed in the printed circuit board PCB. This will be described later in detail with reference to FIGS. 4 and 5.

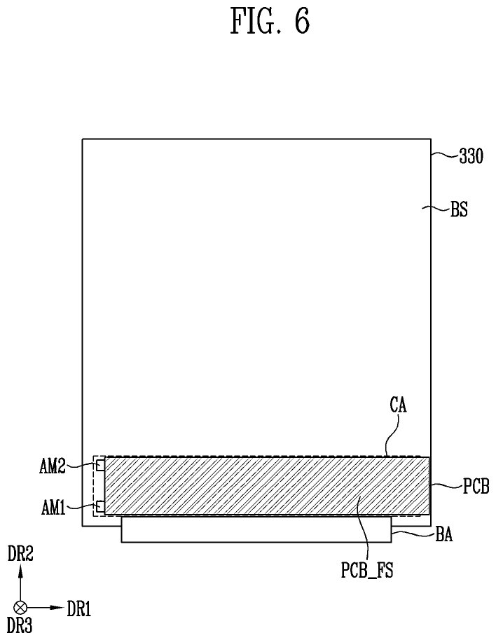

FIG. 4 is a plan view illustrating an embodiment of the shielding layer and the printed circuit board before the bending area shown in FIG. 2 is bent. FIG. 5 is a plan view illustrating an embodiment of the shielding layer and the printed circuit board after the bending area shown in FIG. 2 is bent. FIG. 6 is a plan view illustrating a comparative example in which the printed circuit board shown in FIG. 5 is not successfully aligned on the shielding layer.

Referring to FIGS. 4 and 5, the printed circuit board PCB may include ground areas GA. In addition, the shielding layer 330 may include a contact area CA. In an embodiment, the shielding layer 330 may include the contact area CA disposed at a lower end portion of the back surface BS of the shielding layer 330, for example.

The printed circuit board PCB may include a front surface PCB_FS and a back surface PCB_BS of the printed circuit board PCB. In an embodiment, the printed circuit board PCB may include the ground areas GA, and include the back surface PCB_BS of the printed circuit board PCB, which contacts the shielding layer 330, for example.

The back surface PCB_BS of the printed circuit board PCB may be a ground surface. In an embodiment, the printed circuit board PCB may be configured as a multi-layer, and the back surface PCB_BS of the printed circuit board PCB may be a ground surface disposed at a lowermost end, for example.

The printed circuit board PCB may be disposed to overlap with the contact area CA of the shielding layer 330. In an embodiment, as the bending area BA is bent in the opposite direction of the third direction DR3, the printed circuit board PCB may be disposed to overlap with the back surface BS of the shielding layer 330 in a plan view, for example. The contact area CA may be an area in contact with the back surface BS of the shielding layer 330.

The ground areas GA may be disposed on the back surface PCB_BS of the printed circuit board PCB. In an embodiment, the ground areas GA may be disposed at one side of the back surface PCB_BS of the printed circuit board PCB, for example.

The contact area CA may be covered by the printed circuit board PCB. In an embodiment, the contact area CA may contact the back surface PCB_BS of the printed circuit board PCB, and be covered by the printed circuit board PCB in a plan view, for example.

In some embodiments, the contact area CA may correspond to the printed circuit board PCB. In an embodiment, a shape and a size of the contact area CA may correspond to a shape and a size of the printed circuit board PCB, for example. Therefore, although a case where the contact area CA has a quadrangular shape is illustrated in FIG. 4, the disclosure is not limited thereto, and the contact area CA may have a shape corresponding to the shape of the printed circuit board PCB.

The shielding layer 330 may include conductive members CM. The conductive members CM may be disposed on the contact area CA. In an embodiment, the conductive members CM may be disposed in the first direction DR1 on the back surface BS of the shielding layer 330, for example.

The conductive members CM may include first to fourth conductive members CM1 to CM4. In an embodiment, the conductive members CM may include the first to fourth conductive members CM1 to CM4 each including two or more conductive units, for example. In FIG. 4, it is illustrated that two conductive units included in each of the first to fourth conductive members CM1 to CM4 are disposed. However, the disclosure is not limited thereto.

The conductive members CM may contact the ground areas GA, respectively. In an embodiment, when the back surface PCB_BS of the printed circuit board PCB overlaps with the back surface BS of the shielding layer 330 as the bending area BA is bent, the first to fourth conductive members CM1 to CM4 disposed on the back surface PCB_BS of the printed circuit board PCB may contact first to fourth ground areas GA1 to GA4, respectively, for example.

The conductive members CM may transfer an electromagnetic wave absorbed in the shielding layer 330 to the printed circuit board PCB. In an embodiment, the first to fourth conductive members CM1 to CM4 may contact the first to fourth ground areas GA1 to GA4, respectively, thereby transferring the electromagnetic wave absorbed by the shielding layer 330 to the back surface PCB_BS of the printed circuit board PCB, for example.

In an embodiment of the disclosure, the back surface PCB_BS of the printed circuit board PCB may minimize or at least decrease the intensity of the electromagnetic wave transferred thereto. In an embodiment, the back surface PCB_BS of the printed circuit board PCB may receive an electromagnetic wave transferred from the shielding layer 330 through the ground areas GA in contact with the conductive members CM, for example. The electromagnetic wave supplied to the back surface PCB_BS of the printed circuit board PCB may be absorbed in the back surface PCB BS of the printed circuit board PCB, and the intensity of the electromagnetic wave may be decreased.

Each of the conductive members CM may be a conductive adhesive. In an embodiment, each of the conductive members CM may be an adhesive in which conductive particles are mixed, for example. Accordingly, the conductive members CM are attached to the shielding layer 330, to electrically connect the shielding layer 330 and the printed circuit board PCB to each other. In an embodiment, the conductive members CM may contact the ground areas GA of the printed circuit board PCB, thereby electrically connecting the shielding layer 330 and the printed circuit board PCB to each other, for example.

In some embodiments, the conductive members CM may include a metal material such as gold (Au), nickel (Ni), copper (Cu) or silver (Ag), but the metal material of the conductive members CM is not limited thereto as long as it electrically connects the shielding layer 330 and the printed circuit board PCB to each other.

The shielding layer 330 may include a plurality of alignment marks AM. In an embodiment, the shielding layer 330 may include first to fourth alignment marks AM1 to AM4, for example.

The plurality of alignment marks AM may be disposed on the contact area CA. In an embodiment, the first to fourth alignment marks AM1 to AM4 may be disposed at corners of the contact area CA, respectively, for example.

The plurality of alignment marks AM may be imprinted in the shielding layer 330. In an embodiment, the first to fourth alignment marks AM1 to AM4 may be imprinted at the corners of the contact area CA, respectively, for example.

The plurality of alignment marks AM may have a quadrangular shape, but the disclosure is not limited thereto. In an embodiment, the plurality of alignment marks AM may have a circular shape, a triangular shape, a pentagonal shape, or a rhombic shape, for example. In addition, the first to fourth alignment marks AM1 to AM4 may have different shapes.

The first alignment mark AM1 and the fourth alignment mark AM4 may be symmetrically disposed. In an embodiment, the first alignment mark AM1 and the fourth alignment mark AM4 may be respectively disposed at one side and an opposite side of the shielding layer 330, to be symmetrically disposed with respect to the second direction DR2, for example.

A distance D1 between an outer side (e.g., left side) of the first alignment mark AM1 and an outer side (e.g., right side) of the fourth alignment mark AM4 in a horizontal direction (e.g., the first direction DR1) may be smaller than a length L1 of the printed circuit board PCB in the horizontal direction (e.g., the first direction DR1). Therefore, both the first alignment mark AM1 and the fourth alignment mark AM4 may be covered by the printed circuit board PCB.

The first alignment mark AM1 may be symmetrically disposed with the second alignment mark AM2. In an embodiment, both the first alignment mark AM1 and the second alignment mark AM2 are disposed at one side of the shielding layer 330, and may be symmetrically disposed with respect to the first direction DR1, for example.

A distance D2 between an outer side (e.g., upper side) of the first alignment mark AM1 and an outer side (e.g., lower side) of the second alignment mark AM2 in a vertical direction (e.g., the second direction DR2) may be smaller than a length L2 of the printed circuit board PCB in the vertical direction (e.g., the second direction DR2). Therefore, both the first alignment mark AM1 and the second alignment mark AM2 may be covered by the printed circuit board PCB.

Referring to FIGS. 4 to 6, the plurality of alignment marks AM may be used to check whether the ground areas GA of the printed circuit board PCB have been successfully aligned with respect to the conductive members CM. Therefore, the printed circuit board PCB may be aligned based on the plurality of alignment marks AM. In an embodiment, the printed circuit board PCB may be aligned to cover the first to fourth alignment marks AM1 to AM4, for example. When the first to fourth alignment marks AM1 to AM4 are all covered by the printed circuit board PCB, the first to fourth conductive members CM1 to CM4 may be successfully in contact with the first to fourth ground areas GA1 to GA4, respectively.

As shown in FIG. 6, when portions of the first alignment mark AM1 and the second alignment mark AM2 are not covered by the printed circuit board PCB, at least some of the conductive members CM may not in contact with the ground areas GA. Accordingly, at least a portion of the electromagnetic wave absorbed by the shielding layer 330 may not be transferred to the back surface PCB_BS of the printed circuit board PCB.

In an embodiment of the disclosure, it may be checked whether the conductive members CM have been successfully in contact with the ground areas GA through the plurality of alignment marks AM. In an embodiment, when the first to fourth alignment marks AM1 to AM4 are all covered by the printed circuit board PCB not to be exposed to the outside, it may be visually checked whether the first to fourth conductive members CM1 to CM4 have been successfully in contact with the first to fourth ground areas GA1 to GA4, respectively, for example. Accordingly, it may be checked whether the electromagnetic wave absorbed in the shielding layer has been transferred to the back surface PCB_BS of the printed circuit board PCB without driving the display device 1000 or without performing any separate process, and the reliability of a manufacturing process of the display device 1000 may be improved.

However, the disclosure is not limited to the aligning method. In an embodiment, the printed circuit board PCB does not cover the alignment marks, but may be aligned to be accurately disposed (e.g., mounted) in a frame defined by the alignment marks, for example.

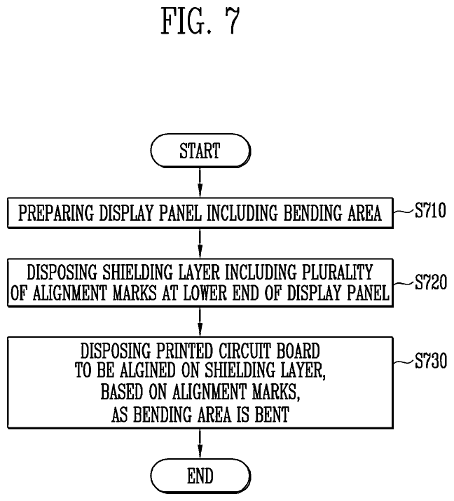

FIG. 7 is a flowchart illustrating an embodiment of a manufacturing method of the display device in accordance with the disclosure.

Referring to FIG. 7, the manufacturing method of the display device 1000 in the embodiment of the disclosure may include operation S710 of preparing a display panel including a bending area, operation S720 of disposing a shielding layer including a plurality of alignment marks at a lower end of the display panel, and operation S730 of disposing a printed circuit board to be aligned on the shielding layer, based on the alignment marks, as the bending area is bent.

Referring to FIGS. 2 and 7, in operation S710, the display panel 200 including the bending area BA may be prepared. The bending area BA may electrically connect the display panel 200 and the printed circuit board PCB to each other. Therefore, the bending area BA may include a connector through which the display panel 200 and the printed circuit board PCB are connected to each other.

Referring to FIGS. 2, 4, and 7, in operation S720, the shielding layer 330 including the plurality of alignment marks AM may be disposed at a lower end of the display panel 200. The shielding layer 330 may be disposed at the lower end of the display panel 200 to overlap with the display panel 200.

Referring to FIGS. 5 and 7, in operation S730, as the bending area BA is bent, the printed circuit board PCB may be aligned on the shielding layer 330, based on the alignment marks AM.

The bending area BA may include a flexible printed circuit board. The bending area BA may be bent in the opposite direction of the third direction DR3. As the bending area BA is bent in the opposite direction of the third direction DR3, the printed circuit board PCB may be disposed to overlap with the shielding layer 330.

The printed circuit board PCB may be aligned based on the plurality of alignment marks AM. In an embodiment, the printed circuit board PCB may be aligned based on whether the back surface PCB_BS of the printed circuit board PCB covers all the first to fourth alignment marks AM1 to AM4, for example.

The ground areas GA of the printed circuit board PCB may contact the conductive member CM. In an embodiment, the first to fourth ground areas GA1 to GA4 of the successfully aligned printed circuit board PCB may contact the first to fourth conductive members CM1 to CM4 while corresponding to the first to fourth conductive members CM1 to CM4, respectively, for example.

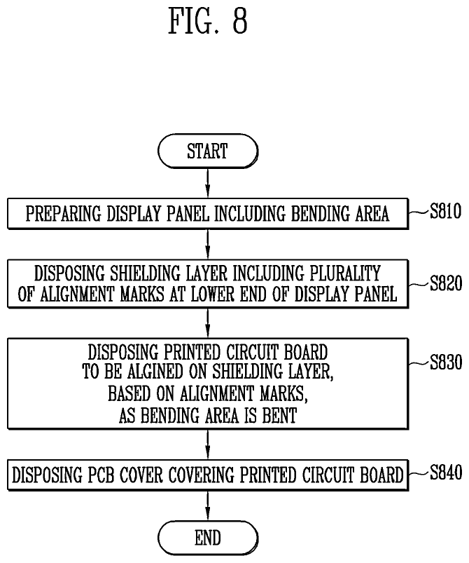

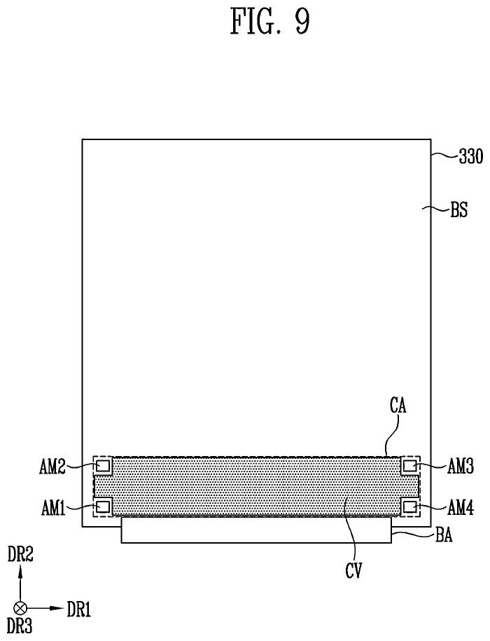

FIG. 8 is a flowchart illustrating a manufacturing method of the display device in accordance with the disclosure. FIG. 9 is a plan view illustrating an embodiment of the shielding layer and a printed circuit board cover in operation S840 shown in FIG. 8.

Referring to FIG. 8, the manufacturing method of the display device 1000 in accordance with the an embodiment of the disclosure may include operation S810 of preparing a display panel including a bending area, operation S820 of disposing a shielding layer including a plurality of alignment marks at a lower end of the display panel, operation S830 of disposing a printed circuit board to be aligned on the shielding layer, based on the alignment marks, as the bending area is bent, and operation S840 of disposing a printed circuit board cover on the printed circuit board.

Operations S810, S820, and S830, which are shown in FIG. 8, may be described identically to operations S710, S720, and S730, which are shown in FIG. 7, and therefore, overlapping descriptions will be omitted below.

Referring to FIGS. 8 to 9, in operation S840, a printed circuit board cover CV may be disposed on the printed circuit board PCB.

The printed circuit board cover CV may cover the printed circuit board PCB. In an embodiment, the printed circuit board cover CV may be disposed on the contact area CA, and cover the printed circuit board PCB, for example.

The printed circuit board cover CV may have a shape substantially identical to the shape of the printed circuit board PCB. In an embodiment, the printed circuit board cover CV may have a quadrangular shape, for example. However, the shape of the printed circuit board cover CV is not limited thereto as long as it may cover the printed circuit board PCB.

In this operation, corners of the printed circuit board cover CV and the printed circuit board PCB may be cut. In an embodiment, the corners of the printed circuit board cover CV and the printed circuit board PCB may be cut such that the first to fourth alignment marks AM1 to AM4 are exposed.

In an embodiment of the disclosure, it may be checked whether the printed circuit board PCB has been successfully aligned by the exposed alignment marks AM. In an embodiment, it may be checked whether the printed circuit board PCB has been successfully aligned in a lateral direction (e.g., the first direction DR1) with respect to the contact area CA, based on whether the first alignment mark AM1 and the fourth alignment mark AM4 are symmetrically disposed with respect to the second direction DR2. In addition, it may be checked whether the printed circuit board PCB has been successfully aligned in a longitudinal direction (e.g., the second direction DR2) with respect to the contact area CA, based on whether the first alignment mark AM1 and the second alignment mark AM2 are symmetrically disposed with respect to the first direction DR1. Accordingly, it may be checked that the printed circuit board PCB has been successfully aligned, and the reliability of the manufacturing process of the display device 1000 may be improved.

In accordance with the disclosure, there may be provided a display device and a manufacturing method thereof, in which a printed circuit board is aligned on a shielding layer, using alignment marks, thereby improving the reliability of a manufacturing process.

Embodiments have been disclosed herein, and although predetermined terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in any combinations with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a display panel;
a shielding layer disposed at a lower end of the display panel, the shielding layer including:
a plurality of alignment marks; and
conductive members; and
a printed circuit board aligned on the shielding layer, based on the plurality of alignment marks, the printed circuit board being in contact with at least a portion of the shielding layer,
wherein the conductive members electrically connect the printed circuit board and the shielding layer to each other.

2. The display device of claim 1, wherein the printed circuit board overlaps with at least a portion of a contact area of the shielding layer, and
wherein the plurality of alignment marks is disposed on the contact area.

3. The display device of claim 2, wherein at least one of the plurality of alignment marks overlaps with the printed circuit board.

4. The display device of claim 2, further comprising a printed circuit board cover covering the printed circuit board,
wherein corners of the printed circuit board and the printed circuit board cover are cut so that the plurality of alignment marks is exposed.

5. The display device of claim 1, wherein the plurality of alignment marks includes a first alignment mark disposed at one side of the shielding layer and a second alignment mark which is disposed at an opposite side of the shielding layer and is symmetrically disposed with the first alignment mark.

6. The display device of claim 5, wherein a distance between an outer side of the first alignment mark and an outer side of the second alignment mark in a predetermined direction perpendicular to a direction in which the shielding layer and the printed circuit board are arranged is smaller than a length of the printed circuit board in the predetermined direction.

7. The display device of claim 5, wherein a distance between an outer side of the first alignment mark and an outer side of the second alignment mark in a predetermined direction in which the shielding layer and the printed circuit board are arranged is smaller than a length of the printed circuit board in the predetermined direction.

8. The display device of claim 1, wherein the shielding layer includes at least one of aluminum and copper.

9. The display device of claim 1, wherein the plurality of alignment marks is imprinted in the shielding layer.

10. A method of manufacturing a display device, the method comprising:
preparing a display panel including a bending area;
disposing a shielding layer including a plurality of alignment marks at a lower end of the display panel; and
aligning a printed circuit board on the shielding layer, based on the plurality of alignment marks, as the bending area is bent,
wherein the shielding layer includes conductive members electrically connecting the printed circuit board and the shielding layer to each other.

11. The method of claim 10, wherein the printed circuit board overlaps with at least a portion of a contact area of the shielding layer, and
wherein the plurality of alignment marks are disposed on the contact area.

12. The method of claim 11, wherein at least one of the plurality of alignment marks overlaps with the printed circuit board.

13. The method of claim 11, further comprising disposing a printed circuit board cover on the printed circuit board,
wherein corners of the printed circuit board and the printed circuit board cover are cut so that the plurality of alignment marks is exposed.

14. The method of claim 10, wherein the plurality of alignment marks includes a first alignment mark disposed at one side of the shielding layer and a second alignment mark which is disposed at an opposite side of the shielding layer and is symmetrically disposed with the first alignment mark.

15. The method of claim 14, wherein a distance between an outer side of the first alignment mark and an outer side of the second alignment mark in a predetermined direction perpendicular to a direction in which the shielding layer and the printed circuit board are arranged is smaller than a length of the printed circuit board in the predetermined direction.

16. The method of claim 14, wherein a distance between an outer side of the first alignment mark and an outer side of the second alignment mark in a predetermined direction in which the shielding layer and the printed circuit board are arranged is smaller than a length of the printed circuit board in the predetermined direction.

17. The method of claim 10, wherein the shielding layer includes at least one of aluminum and copper.

18. The method of claim 10, wherein the plurality of alignment marks is imprinted in the shielding layer.
